(19) United States
(12) Patent Application Publication
(10) Pub. No.: US 2025/0234747 A1
(43) Pub. Date: Jul. 17, 2025

(54) DISPLAY DEVICE

(71) Applicant: LG Display Co., Ltd., Seoul (KR)

(72) Inventors: Hyunsuk LEE, Paju-si (KR); Hyesook KIM, Paju-si (KR); SangWook LEE, Paju-si (KR)

(21) Appl. No.: 19/020,618

(22) Filed: Jan. 14, 2025

(30) Foreign Application Priority Data
Jan. 17, 2024 (KR) 10-2024-0007364

(51) Int. Cl. H10K 59/80; H10K 59/124

(52) U.S. Cl. CPC H10K 59/80521; H10K 59/124; H10K 59/873

(57) ABSTRACT

Embodiments of the present disclosure relate to a display device. A display device may include a substrate including a display area and a non-display area, an undercut protrusion disposed on the substrate and disposed in the non-display area, an emission layer including an undercut emission layer separated on the undercut protrusion, a first cathode layer disposed on the emission layer and including an undercut cathode layer separated on the undercut protrusion, and a first insulating layer disposed to cover the first cathode layer, thereby preventing the damage of the light emission layer.

### CROSS-REFERENCE TO RELATED APPLICATION

This application claims priority from Korean Patent Application No. 10-2024-0007364, filed on Jan. 17, 2024, which is hereby incorporated by reference for all purposes as if fully set forth herein.

### BACKGROUND

### Technical Field

Embodiments of the present disclosure relate to a display device.

### Description of the Related Art

As the information society develops, there is increasing the demand for display devices for displaying images in various forms. Therefore, in recent years, there have been used various display devices such as liquid crystal displays and organic light emitting display devices.

A display device may include a pixel electrode, a light emission layer, and a common electrode. Alternatively, the display device may include an anode electrode, a light emission layer, and a cathode electrode.

In the case that the light emission layer is exposed to water or oxygen, the light emission layer may be damaged. The display panel may thus also be damaged.

### BRIEF SUMMARY

Embodiments of the present disclosure may provide a display device including an insulating film capable of blocking an external material.

Embodiments of the present disclosure may provide a display device including an insulating film capable of preventing damage to a light emission layer.

Embodiments of the present disclosure may provide a display device capable of low power consumption by preventing the damage of a light emission layer.

A display device according to embodiments of the present disclosure may include a substrate including a display area and a non-display area, an undercut protrusion disposed on the substrate and disposed in the non-display area, an emission layer including an undercut emission layer separated on the undercut protrusion, a first cathode layer disposed on the emission layer and including an undercut cathode layer separated on the undercut protrusion, and a first insulating layer disposed to cover the first cathode layer.

The first insulating layer may be disposed between the passivation layer of the undercut protrusion and the emission layer.

The first insulating layer may be disposed on the outside of the emission layer corresponding to the display area.

The substrate may include a first area where the passivation layer overlaps the electrode, and a second area where the passivation layer does not overlap the electrode. The first insulating layer may be disposed to surround the second area.

According to embodiments of the present disclosure, it is possible to provide a display device including an insulating film capable of blocking an external material.

According to embodiments of the present disclosure, it is possible to provide a display device including an insulating film capable of preventing damage to a light emission layer.

According to embodiments of the present disclosure, it is possible to provide a display device capable of low power consumption by preventing the damage of a light emission layer.

### BRIEF DESCRIPTION OF THE SEVERAL VIEWS OF THE DRAWINGS

FIG. 1 is a system configuration diagram of a display device according to embodiments of the present disclosure.

FIG. 2 illustrates a display panel according to embodiments of the present disclosure.

FIG. 3 illustrates a display panel according to embodiments of the present disclosure.

FIGS. 4 and 5 are cross-sectional views of display panels according to embodiments of the present disclosure.

FIGS. 6 and 7 are cross-sectional views of a display panel with a display area and a non-display area according to embodiments of the present disclosure.

FIGS. 8 and 9 are cross-sectional views of the display panel for the display area according to embodiments of the present disclosure.

FIG. 10 illustrates a base voltage pad disposed on a display panel according to embodiments of the present disclosure.

FIG. 11 is a cross-sectional view of a base voltage pad according to embodiments of the present disclosure.

FIG. 12 illustrates a base voltage pad disposed on a display panel according to embodiments of the present disclosure.

FIGS. 13 and 14 are cross-sectional views of base voltage pads according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range (e.g., 5%) that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

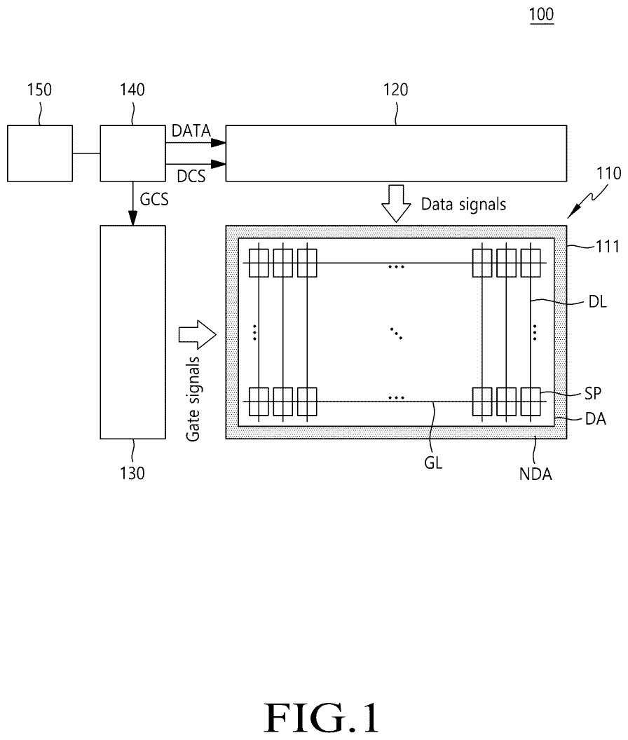

FIG. 1 is a system configuration diagram of a display device 100 according to embodiments of the present disclosure.

Referring to FIG. 1, a display device 100 according to embodiments of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA located outside the display area DA.

A plurality of subpixels SP for image display may be disposed in the display area DA, and the non-display area NDA may include a pad area PA located in the first direction from the display area DA.

In a display panel 110 according to embodiments of the present disclosure, the non-display area NDA may be very small. In this specification, the non-display area NDA may be also referred to as a “bezel.”

For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction. One or both of the first to fourth non-display areas may include a pad area to which the data driving circuit 120 is connected or bonded. Among the first to fourth non-display areas, two or three which do not include the pad area may be very small in size.

For another example, a boundary area between the display area DA and the non-display area NDA may be bent so that the non-display area NDA may be located below the display area. In this case, when the user looks at the display device 100 from the front, there may be little or no non-display area NDA visible to the user.

Various types of signal lines for driving a plurality of subpixels SP may be disposed on the substrate 111 of the display panel 110.

The display device 100 according to embodiments of the present disclosure may be a liquid crystal display device or the like, or may be a self-luminous display device in which the display panel 110 emits light by itself. When the display device 100 according to embodiments of the present disclosure is a self-luminous display device, each of the plurality of subpixels SP may include a light emitting device.

For example, the display device 100 according to embodiments of the present disclosure may be an organic light emitting display device in which a light emitting device is implemented as an organic light emitting diode (OLED). For another example, the display device 100 according to embodiments of the present disclosure may be an inorganic light emitting display device in which the light emitting device is implemented as an inorganic-based light emitting diode. For another example, the display device 100 according to embodiments of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will be exemplified a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data lines DL.

For example, the data driving circuit 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to embodiments of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

In the display device 100 according to embodiments of the present disclosure, the gate driving circuit 130 may be disposed in the display area DA of the display panel 110. For example, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area (e.g., a right area or a left area within the display area DA).

In the present disclosure, a gate driving circuit 130 built into the display panel 110 as a gate-in-panel type may be referred to as a “gate-in-panel circuit.”

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology, or may be a control device capable of further performing other control functions including a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor.

The display controller 140 may be mounted on a printed circuit board, a flexible printed circuit, etc., and may be electrically connected to the data driving circuit 120 and the gate driving circuit 130 through a printed circuit board, a flexible printed circuit.

The display controller 240 may transmit and receive signals with the data driving circuit 120 according to one or more predetermined interfaces. For example, the interface may include a low voltage differential signaling (LVDS) interface, an embedded clock point-point interface (EPI) interface, or a serial peripheral interface (SPI).

In order to provide not only an image display function but also a touch sensing function, the display device 100 according to embodiments of the present disclosure may include a touch sensor and a touch sensing circuit for detecting an occurrence of a touch by a touch object such as a finger or pen or detection a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

The touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit 260 may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit and the data driving circuit may be implemented as separate devices or as one device.

The display device 100 may further include a power supply circuit which supplies various types of power to the display driving circuit and/or the touch sensing circuit.

The display device 100 according to embodiments of the present disclosure may be a mobile terminal such as a smart phone or tablet, or a monitor or television of various sizes, but is not limited thereto, and may be a display of various types and sizes capable of displaying information or images.

The display device 100 according to embodiments of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

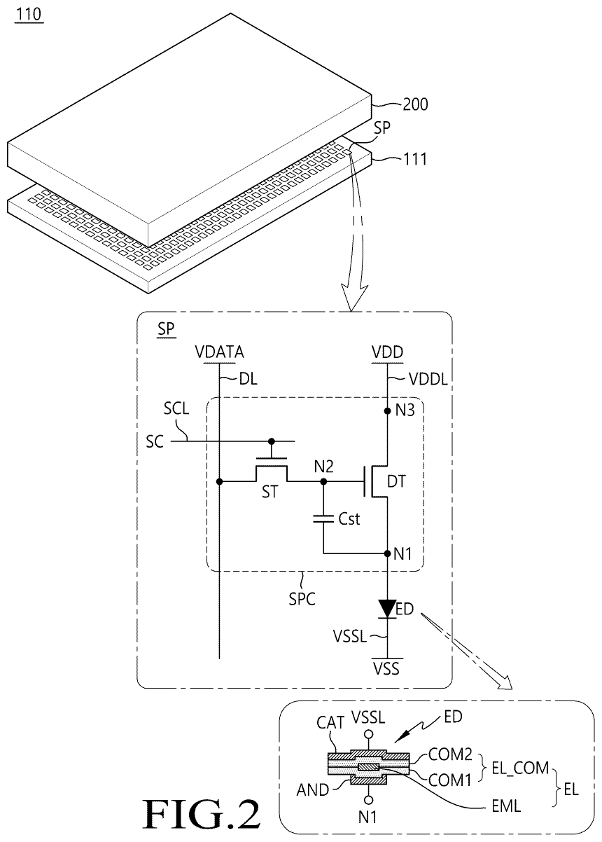

Referring to FIG. 2, the display panel 110 may include a substrate 111 disposed in a plurality of subpixels SP and an encapsulation layer 200 on the substrate 111. Here, the encapsulation layer 200 may also be referred to as an encapsulation substrate or an encapsulation portion.

Referring to FIG. 2, when the display device 100 according to embodiments of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DT for driving the light emitting device ED, and a scan transistor ST which is turned on or off depending on the scan signal SC.

The driving transistor DT may supply driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during the frame.

In order to drive the subpixel SP, a data signal VDATA which is an image signal, and a scan signal SC which is a gate signal may be applied to the subpixel SP. In addition, a common pixel driving voltage including a first driving voltage VDD and a second driving voltage VSS may be applied to the subpixel SP in order to drive the subpixel SP.

The light emitting device ED may include an anode AND, a light emitting device intermediate layer EL, and a cathode CAT. The light emitting device intermediate layer EL may be a layer disposed between the anode AND and the cathode CAT.

In the case that the light emitting device ED is an organic light emitting device, the light emitting device intermediate layer EL may include an emission layer EML, a first common intermediate layer COM1 between the anode AND and the emission layer EML, and a second common intermediate layer COM2 between the emission layer EML and the cathode. The emission layer EML may be disposed in each subpixel SP. In comparison, the first common intermediate layer COM1 and the second common intermediate layer COM2 may be commonly disposed across a plurality of subpixels SP. The emission layer EML may be disposed in each emission area, and the first common intermediate layer COM1 and the second common intermediate layer COM2 may be commonly disposed across a plurality of emission areas and non-emission areas. The first common intermediate layer COM1 and the second common intermediate layer COM2 may be collectively referred to as a common intermediate layer EL_COM.

For example, the first common intermediate layer COM1 may include a hole injection layer HIL and a hole transport layer HTL. The second common intermediate layer COM2 may include an electron transport layer ETL and an electron injection layer EIL. The hole injection layer may inject holes from the anode AND to the hole transport layer, the hole transport layer may transport holes to the emission EML, the electron injection layer may inject electrons from the cathode CAT to the electron transport layer, and the electron transport layer may transport electrons to the emission layer EML.

For example, the cathode CAT may be electrically connected to a second common driving voltage line VSSL. A second common driving voltage VSS, which is a type of common pixel driving voltage, may be applied to the cathode CAT through the second common driving voltage line VSSL. The anode AND may be electrically connected to a first node N1 of the driving transistor DT of each subpixel SP. In the present disclosure, the second common driving voltage VSS may also be referred to as a base voltage VSS, and the second common driving voltage line VSSL may also be referred to as a base voltage line VSSL.

For example, the anode AND may be a pixel electrode disposed in each subpixel SP, and the cathode CAT may be a common electrode commonly disposed in a plurality of subpixels SP. For another example, the cathode CAT may be a pixel electrode disposed in each subpixel SP, and the anode AND may be a common electrode commonly disposed in a plurality of subpixels SP. Hereinafter, for convenience of explanation, it is assumed that the anode AND is a pixel electrode and the cathode CAT is a common electrode.

Each light emitting device ED may be composed of overlapping parts of an anode AND, a light emitting device intermediate layer EL and a cathode CAT. A predetermined emission area may be formed by each light emitting device ED. For example, the emission area of each light emitting device ED may include an area where the anode AND, the light emitting device intermediate layer EL and the cathode CAT overlap.

For example, the light emitting device ED may be an organic light emitting diode (OLED), an inorganic light emitting diode, or a quantum dot light emitting device. For example, in the case that the light emitting device ED is an organic light emitting diode OLED, the light emitting device intermediate layer EL in the light emitting device ED may include an organic light emitting device intermediate layer EL containing an organic material.

The driving transistor DT may be a driving transistor for supplying driving current to the light emitting device ED. The driving transistor DT may be connected between a first common driving voltage line VDDL and the light emitting device ED.

The driving transistor DT may include a first node N1 electrically connected to the light emitting device ED, a second node N2 to which the data signal VDATA is applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA, which is an image signal, to the second node N2 which is the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in the vertical direction. Alternatively, if the display panel 110 has a bottom emission structure, the subpixel circuit SPC may not overlap with the light emitting device ED in the vertical direction.

As shown in FIG. 2, the subpixel circuit SPC may have 2T-1C structure including two transistors T1 and T2 and one capacitor Cst. In some case, the subpixel circuit SPC may further include one or more transistors or one or more capacitors.

For example, the subpixel circuit SPC may have a 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP.

In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent oxygen from penetrating into the circuit elements (particularly, the light emitting device ED). The encapsulation layer 200 may be configured in various shapes to prevent the light emitting device ED from coming into contact with moisture or oxygen.

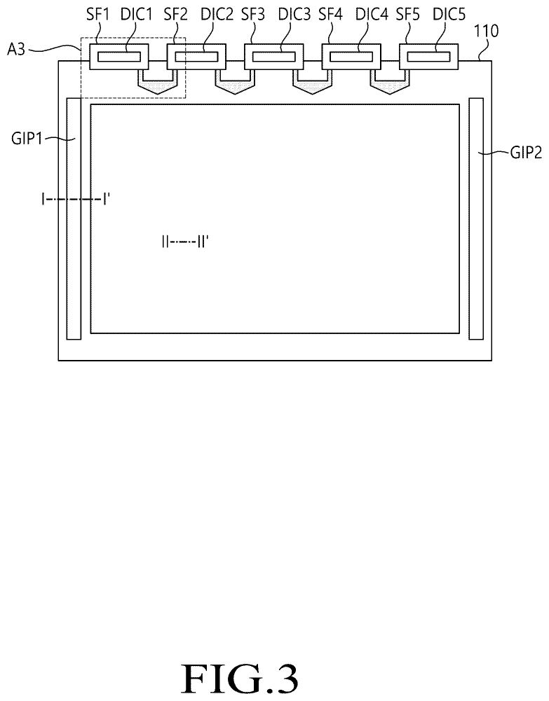

FIG. 3 illustrates a display panel 110 according to embodiments of the present disclosure.

The display panel 110 may include a display area DA and a non-display area NDA.

The display panel 110 may include two gate driving circuits GIP. A first gate driving circuit GIP1 and a second gate driving circuit GIP2 may be disposed on the left and right sides of the display panel 110, respectively.

The display panel 110 may be combined with a plurality of source films SF1, SF2, SF3, SF4 and SF5. The plurality of source films may include a first source film SF1, a second source film SF2, a third source film SF3, a fourth source film SF4, and a fifth source film SF5. Each of the first source film SF1, the second source film SF2, the third source film SF3, the fourth source film SF4, and the fifth source film SF5 may include a driving integrated circuit DIC1, DIC2, DIC3, DIC4 and DIC5.

A plurality of voltage supply lines (not shown) may be disposed in each of the plurality of source films SF1, SF2, SF3, SF4 and SF5. The plurality of voltage supply lines may supply voltages required for driving, such as a data voltage, a driving voltage, and a base voltage.

Two source films adjacent to each other may share one base voltage pad SPAD. The base voltage pad SPAD may be a pad to which base voltage is supplied. Referring to FIG. 3, the first source film SF1 may share one base voltage pad SPAD with the second source film SF2.

Referring to FIG. 3, there is illustrated an area indicated by I-I′, an area indicated by II-II′, and an third area A3.

Referring to FIG. 3, the area indicated by I-I′ may be a cross-sectional area related to the display area DA and the non-display area NDA.

Referring to FIG. 3, the area indicated by II-II′ may be a cross-sectional area related to the display area DA.

Referring to FIG. 3, the third area A3 may be an area where the base voltage pad SPAD is disposed.

Hereinafter, the area indicated by I-I′, the area indicated by II-II′, and the third area A3 will be described in detail.

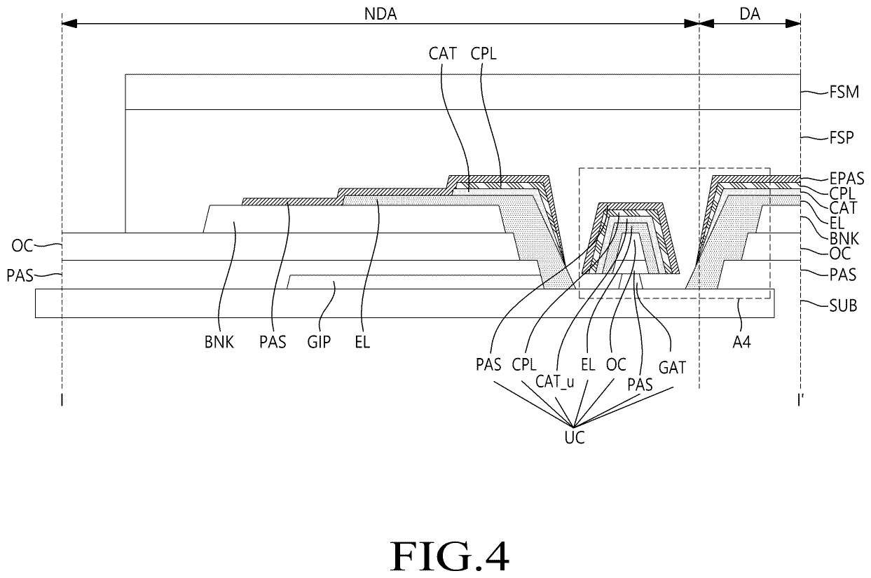

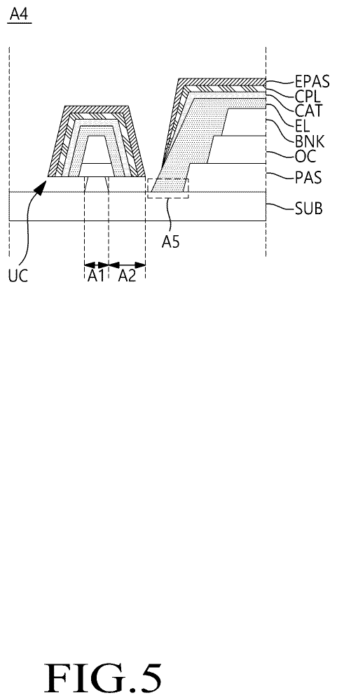

FIGS. 4 and 5 are cross-sectional views of a display panel 110 according to embodiments of the present disclosure.

FIG. 4 illustrates a cross-sectional view of the area indicated by I-I′ shown in FIG. 3.

A substrate SUB may be disposed at the bottom of the display panel 110. Referring to FIG. 4, the substrate SUB is illustrated as being disposed at the bottom, but the substrate SUB may be disposed below a polarizer, a cover glass, etc.

A gate driving circuit GIP may be disposed on the substrate SUB corresponding to the non-display area NDA. The gate driving circuit GIP may be a gate-in-panel type formed on the display panel 110.

A gate electrode GAT may be disposed on the substrate SUB. The gate electrode GAT may be disposed to be spaced apart from the gate driving circuit GIP.

A passivation layer PAS may be disposed to cover the gate driving circuit GIP and the gate electrode GAT.

An overcoating layer OC may be disposed on the passivation layer PAS. The overcoating layer OC may be etched in the process of forming an undercut protrusion UC, and may be divided into three parts. The overcoating layer OC may include a first part corresponding to the display area DA, a second part corresponding to the non-display area NDA, and a third part corresponding to the undercut protrusion.

A bank layer BNK may be disposed on the overcoating layer OC. The bank layer BNK may be etched in the process of forming the undercut protrusion UC, and may be divided into three parts. The bank layer BNK may include a first part corresponding to the display area DA, a second part corresponding to the non-display area NDA, and a third part corresponding to the undercut protrusion.

Referring to FIG. 4, in order to form an undercut protrusion UC, a portion of each of the passivation layer PAS, the overcoating layer OC, and the bank layer BNK may be etched and removed.

The undercut protrusion UC may be disposed outside the display panel 110. Assuming that the display panel 110 has four sides, the undercut protrusion UC may be disposed on three sides of the display panel 110 or on the outside corresponding to the four sides of the display panel 110.

The undercut protrusion UC may include a gate electrode GAT, a passivation layer PAS, and an overcoating layer OC. The undercut protrusion UC may be spade-shaped or mushroom-shaped.

After the undercut protrusion UC is formed, the emission layer EL may be disposed to cover the bank layer BNK and the overcoating layer OC. The emission layer EL may include a first part corresponding to the display area DA, a second part corresponding to the non-display area NDA, and a third part corresponding to the undercut protrusion.

In this case, due to the undercut protrusion UC, the emission layer EL may be disposed in a partially separated state. The emission layer EL may be disposed in contact with the overcoating layer OC of the undercut protrusion UC, but the emission layer EL may be disposed without contacting the gate electrode GAT of the undercut protrusion UC.

Referring to FIG. 4, the emission layer EL disposed on the undercut protrusion UC may be defined as an undercut emission layer EL. The emission layer EL may be disposed on the right side of the undercut protrusion UC, and which may be defined as a display area emission layer EL. The emission layer EL may be disposed on the left side of the undercut protrusion UC, and which may be referred to as a non-display area emission layer EL.

A cathode layer CAT may be disposed on the emission layer EL. Due to the undercut protrusion UC, the cathode layer CAT may be disposed in a partially separated state. The cathode layer CAT may include a first part corresponding to the display area DA, a second part corresponding to the non-display area NDA, and a third part corresponding to the undercut protrusion. The cathode layer CAT may include a non-display area cathode layer CAT disposed on the non-display area emission layer EL, an undercut cathode layer CAT1_u disposed on the undercut emission layer EL, and a display area cathode layer CAT disposed on the display area emission layer EL.

A capping layer CPL may be disposed on the cathode layer CAT. Due to the undercut protrusion UC, the capping layer CPL may be disposed in a partially separated state. The capping layer CPL may include a first part corresponding to the display area DA, a second part corresponding to the non-display area NDA, and a third part corresponding to the undercut protrusion.

An encapsulation layer EPAS may be disposed on the capping layer CPL. Due to the undercut protrusion UC, the encapsulation layer EPAS may be disposed in a partially separated state. The encapsulation layer EPAS may include a first part corresponding to the display area DA, a second part corresponding to the non-display area NDA, and a third part corresponding to the undercut protrusion.

An adhesive layer FSP may be disposed on the encapsulation layer EPAS. Since the adhesive layer FSP is deposited on the entire surface, the encapsulation layer EPAS may be disposed in both the display area DA and the non-display area NDA.

A metal encapsulation layer FSM may be disposed on the adhesive layer FSP. The metal encapsulation layer FSM may be disposed on the top of the display panel 110.

Meanwhile, referring to FIGS. 4 and 5, there is illustrated a fourth area A4, which is an enlarged area around the undercut protrusion UC. Referring to FIG. 5, the display area emission layer EL disposed in the display area DA may be exposed to oxygen or water through a fifth area A5. If the emission layer EL is exposed to oxygen or water, there may be occurred the defects in the emission layer EL.

If the cathode layer CAT is disposed on the emission layer EL, the cathode layer CAT may be formed through a physical vapor deposition (PVD) process. The PVD process may be performed by an evaporation method and a sputtering method. If the sputtering method is applied, the cathode layer CAT may be disposed to cover the entire emission layer EL. However, if the evaporation method is applied, the cathode layer CAT may be disposed while exposing the lower end of the emission layer EL.

The emission layer EL and cathode layer CAT may be formed through an evaporation method. If the evaporation method is applied, there may be a problem of insufficient step coverage. If the step coverage is insufficient, the deposition thickness on the side portion may be thin. The thickness of the cathode layer CAT may be thinner than the thickness of the emission layer EL. In this case, the step coverage where the cathode layer CAT covers the emission layer EL may be further reduced, and accordingly, the cathode layer CAT may be disposed while exposing the lower end of the emission layer EL.

This may correspond to an arrangement of the cathode layer CAT and the emission layer EL shown in a fifth area A5. Oxygen or water may flow into the emission layer EL through this area. If the emission layer EL is exposed to oxygen or water, there may be occurred the defects in the emission layer EL.

Accordingly, embodiments of the present disclosure may provide a display device 100 including an insulating film capable of blocking external substances.

Embodiments of the present disclosure may provide a display device 100 including an insulating film capable of preventing the damage of the emission layer EL.

Embodiments of the present disclosure may provide a display device 100 capable of low power consumption by preventing damage to the emission layer EL. Hereinafter, it will be explained in detail.

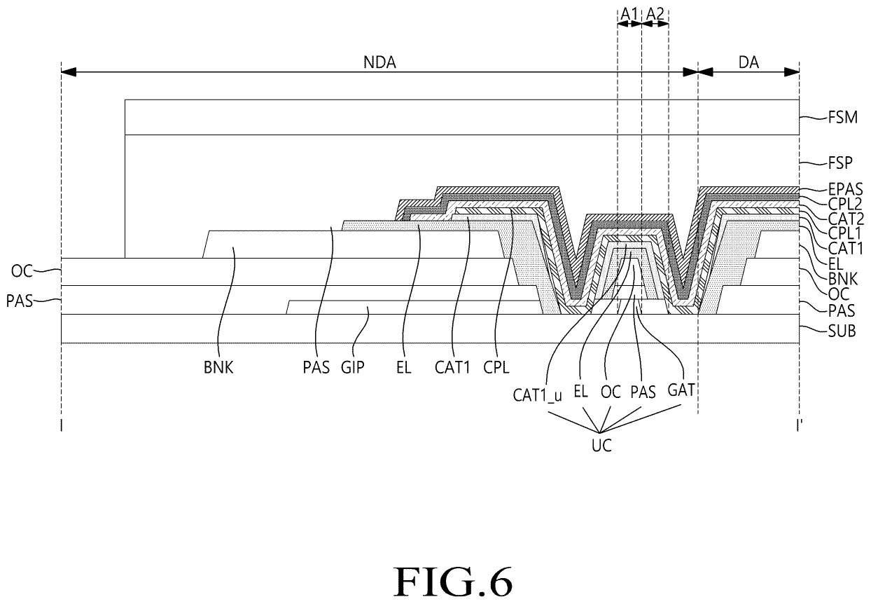

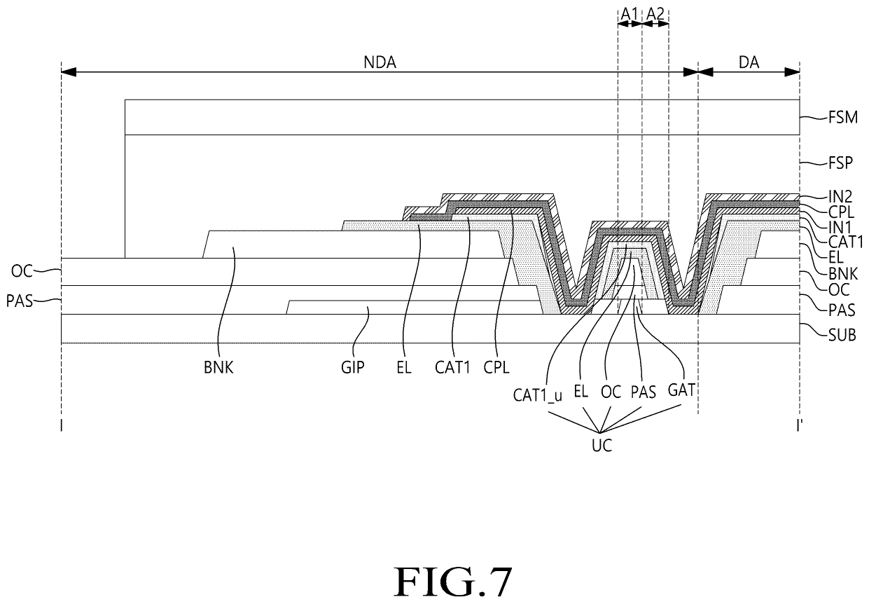

FIGS. 6 and 7 are cross-sectional views of a display panel 110 for a display area DA and a non-display area NDA according to embodiments of the present disclosure.

Referring to FIGS. 6 and 7, there is illustrated a cross-sectional view of the area I-I′ shown in FIG. 3.

Among the configurations of the display panel 110 shown in FIGS. 6 and 7, there may be omitted the descriptions of configurations which are the same as those of the display panel 110 shown in FIG. 5.

Referring to FIG. 6, the substrate SUB may be disposed at the bottom of the display panel 110.

A gate driving circuit GIP may be disposed on the substrate SUB. The gate driving circuit GIP may be a gate-in-panel type formed on the display panel 110.

A gate electrode GAT may be disposed on the substrate SUB and spaced apart from the gate driving circuit GIP.

A passivation layer PAS may be disposed on the overcoating layer OC and the gate electrode GAT.

The overcoating layer OC may be disposed on the passivation layer PAS. The overcoating layer OC may be etched in the process of forming the undercut protrusions UC, and may be divided into three parts. The overcoating layer OC may include a first part corresponding to the display area DA, a second part corresponding to the non-display area NDA, and a third part corresponding to the undercut protrusion.

A bank layer BNK may be disposed on the overcoating layer OC. The bank layer BNK may be disposed on the overcoating layer OC. The bank layer BNK may be etched in the process of forming the undercut protrusion UC, and may be divided into three parts. The bank layer BNK may include a first part corresponding to the display area DA, a second part corresponding to the non-display area NDA, and a third part corresponding to the undercut protrusion.

The undercut protrusion UC may be disposed on the substrate SUB. The undercut protrusion UC may include a gate electrode GAT disposed on the substrate SUB, and a passivation layer PAS disposed on the gate electrode GAT.

The emission layer EL may be disposed on the bank layer BNK and the undercut protrusion UC. The emission layer EL may include a first part corresponding to the display area DA, a second part corresponding to the non-display area NDA, and a third part corresponding to the undercut protrusion. The emission layer EL may include a display area emission layer EL, an undercut emission layer EL, and a non-display area emission layer EL. The thickness of the emission layer EL may be, for example, about 4500 angstroms.

A first cathode layer CAT1 may be disposed on the emission layer EL. The cathode layer CAT may include a first part corresponding to the display area DA, a second part corresponding to the non-display area NDA, and a third part corresponding to the undercut protrusion. The first cathode layer CAT1 may include a non-display area cathode layer CAT, an undercut cathode layer CAT1_u, and a display area cathode layer CAT. The thickness of the first cathode layer CAT1 may be, for example, about 1500 angstroms.

Referring to FIG. 6, a first capping layer CPL1 may be disposed on the first cathode layer CAT1. The first capping layer CPL1 may be disposed to cover the first cathode layer CAT1 and the undercut protrusion UC. The thickness of the first capping layer CPL1 may be, for example, about 5000 angstroms or more than 5000 angstroms. Since the first capping layer CPL1 is disposed to be relatively thicker than the emission layer EL and the first cathode layer CAT1, the first capping layer CPL1 may prevent air or moisture from penetrating into the emission layer EL. If the thickness of the emission layer EL and the first cathode layer CAT1 are designed to be different, the thickness of the first capping layer CPL1 may also be designed to be changed.

A second cathode layer CAT2 may be disposed on the first capping layer CPL1.

The second cathode layer CAT2 may be disposed in contact with the first cathode layer CAT1 in the non-display area NDA. The thickness of the second cathode layer CAT2 may be, for example, about 1500 angstroms. Since the second cathode layer CAT2 is disposed to cover the first capping layer CPL1, the second cathode layer CAT2 may prevent air or moisture from penetrating into the emission layer EL.

A second capping layer CPL2 may be disposed on the second cathode layer CAT2.

The second capping layer CPL2 may be disposed to cover the second cathode layer CAT2. The thickness of the second capping layer CPL2 may be, for example, about 300 angstroms. Since the second capping layer CPL2 is disposed to cover the second cathode layer CAT2, the second capping layer CPL2 can prevent air or moisture from penetrating into the emission layer EL.

An encapsulation layer EPAS may be disposed on the second capping layer CPL2. An adhesive layer FSP may be disposed on the encapsulation layer EPAS, and a metal encapsulation layer FSM may be disposed on the adhesive layer FSP. The thickness of the encapsulation layer EPA may be, for example, about 7000 Angstroms. Since the encapsulation layer EPAS is disposed to cover the second capping layer CPL2, the encapsulation layer EPAS can prevent air or moisture from penetrating into the emission layer EL.

Referring to FIG. 6, the first capping layer CPL1 may be disposed between the passivation layer PAS and the emission layer EL. Since the first capping layer CPL1 is disposed between the passivation layer PAS and the emission layer EL, it is possible to prevent external substances from penetrating into the display area emission layer EL.

Referring to FIG. 6, the first capping layer CPL1 may be disposed outside the emission layer EL corresponding to the display area DA. Since the first capping layer CPL1 is disposed on the outside of the emission layer EL corresponding to the display area DA, it is possible to prevent external substances from penetrating into the display area emission layer EL.

Referring to FIG. 6, the substrate SUB may include a first area A1 where the passivation layer PAS overlaps the electrode, and a second area A2 where the passivation layer PAS does not overlap the electrode. That is, there may be an empty space between the substrate SUB and the passivation layer PAS. However, this space may be filled by the first capping layer CPL1.

Referring to FIG. 6, the first capping layer CPL1 may be disposed to surround the second area A2. Since the first capping layer CPL1 is disposed to surround the second area A2, it is possible to prevent the external substances from penetrating into the display area emission layer EL.

Since the first capping layer CPL1 is disposed to cover the undercut protrusion UC and the display area cathode layer, it is possible to prevent external substances from penetrating into the display area emission layer EL. In addition, since the second cathode layer CAT2 and the second capping layer CPL2 are disposed, there may be further prevented the penetration of external substances.

Referring to FIG. 7, there is illustrated a structure of another display panel 110 capable of preventing the penetration of external substances into the display area emission layer EL.

Referring to FIG. 7, the substrate SUB may be disposed at the bottom of the display panel 110.

A gate driving circuit GIP may be disposed on the substrate SUB. The gate driving circuit GIP may be a gate-in-panel type formed on the display panel 110.

A gate electrode GAT may be disposed on the substrate SUB, and may be disposed spaced apart from the gate driving circuit GIP.

A passivation layer PAS may be disposed on an overcoating layer OC and the gate electrode GAT.

The overcoating layer OC may be disposed on the passivation layer PAS.

A bank layer BNK may be disposed on the overcoating layer OC.

An undercut protrusion UC may be disposed on the substrate SUB. The undercut protrusion UC may include a gate electrode GAT disposed on the substrate SUB, and a passivation layer PAS disposed on the gate electrode GAT.

An emission layer EL may be disposed on the bank layer BNK and the undercut protrusion UC. The emission layer EL may include a first part corresponding to the display area DA, a second part corresponding to the non-display area NDA, and a third part corresponding to the undercut protrusion. The emission layer EL may include a display area emission layer EL, an undercut emission layer EL, and a non-display area emission layer EL.

A first cathode layer CAT1 may be disposed on the emission layer EL. The cathode layer CAT may include a first part corresponding to the display area DA, a second part corresponding to the non-display area NDA, and a third part corresponding to the undercut protrusion. The first cathode layer CAT1 may include a non-display area cathode layer CAT, an undercut cathode layer CAT1_u, and a display area cathode layer CAT.

Referring to FIG. 7, a first insulating layer IN1 may be disposed to cover the first cathode layer CAT1 and the undercut protrusion UC. The first insulating layer IN1 may be a layer capable of blocking oxygen and moisture. The first insulating layer IN1 may include an inorganic insulating material.

A capping layer CPL may be disposed on the first insulating layer IN1. The capping layer CPL may be disposed in contact with the first cathode layer CAT1 in the non-display area NDA.

A second insulating layer IN2 may be disposed on the capping layer CPL. The second insulating layer IN2 may be disposed to cover the capping layer CPL. The second insulating layer IN2 may include an inorganic insulating material.

The inorganic insulating materials included in the first insulating layer IN1 and the second insulating layer IN2 may be as follows. For example, the first insulating layer IN1 and the second insulating layer IN2 may include any one of Al₂O₃, Al:HfO₂, Al:ZnO, AlGaN, Box, BiFeO₃, CeO₂, Co₃O₄, CoFe₂O₄, Er₂O₃, Fe₂O₃, Fe₃O₄, FePO₄, Ga₂O₃, HfO₂, HfSiON, In₂O₃, ITO, La₂O₃, Li₂O, Li₃PO₄, LiPON, LiFePO₄, Li₂MNO₄, Li₅TaOz, MgO, MnO₂, MoO₃, NaTiO, Nb₂O₅, NiFe₂O₄, NiO, Po₄, SiO₂, SnO₂, SrO, SrTiO₃, Ta₂O₅, TiO₂, V₂O₅, WO₃, Y₂O₃, YSZ, ZNal₂O₄, ZnO, ZnMgO, ZNoS, and ZrO₂.

An encapsulation layer EPAS may be disposed on the second insulating layer IN2. An adhesive layer FSP may be disposed on the encapsulation layer EPAS, and a metal encapsulation layer FSM may be disposed on the adhesive layer FSP.

Since the first insulating layer IN1 is disposed to cover the undercut protrusion UC and the display area cathode, it is possible to prevent external substances from penetrating into the display area emission layer EL. In addition, since the capping layer CPL and the second insulating layer IN2 are disposed, there may be further prevented the penetration of external substances.

Referring to FIG. 7, the first insulating layer IN1 may be disposed between the passivation layer PAS and the emission layer EL. Since the first insulating layer IN1 is disposed between the passivation layer PAS and the emission layer EL, it is possible to prevent the external substances from penetrating into the display area emission layer EL.

Referring to FIG. 7, the first insulating layer IN1 may be disposed outside the emission layer EL corresponding to the display area DA. Since the first insulating layer IN1 is disposed on the outside of the emission layer EL corresponding to the display area DA, it is possible to prevent external substances from penetrating into the display area emission layer EL.

Referring to FIG. 7, the substrate SUB may include a first area A1 where the passivation layer PAS overlaps the electrode, and a second area A2 where the passivation layer PAS does not overlap the electrode. That is, there may exist an empty space between the substrate SUB and the passivation layer PAS. However, this space may be filled with the first insulating layer IN1.

Referring to FIG. 7, the first insulating layer IN1 may be disposed to surround the second area A2. As the first insulating layer IN1 is disposed to surround the second area A2, it is possible to prevent the external substances from penetrating into the display area emission layer EL.

Referring to FIGS. 6 and 7, the display device 100 may include a passivation layer PAS disposed on the substrate SUB, and an overcoating layer OC disposed on the passivation layer PAS in the display area DA, a bank layer BNK disposed on the overcoating layer OC, a display area emission layer EL disposed on the bank layer BNK and disposed in the display area DA, and a display area cathode layer CAT disposed on the display area emission layer EL.

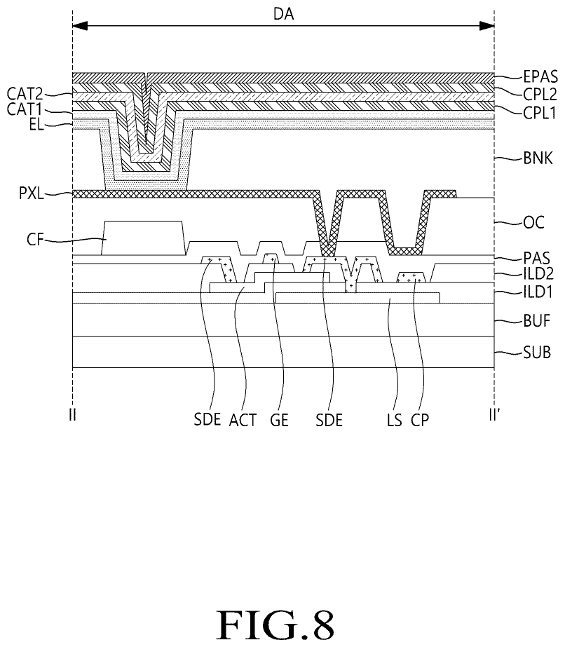

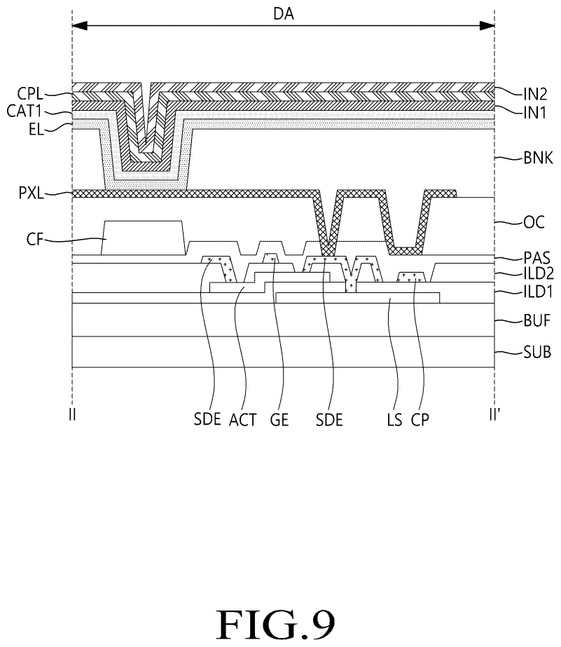

FIGS. 8 and 9 are cross-sectional views of the display panel for the display area DA according to embodiments of the present disclosure.

Referring to FIGS. 8 and 9, there is illustrated a cross-sectional view of the area I-I′ shown in FIG. 3.

Referring to FIGS. 8 and 9, a substrate SUB may be disposed at the bottom of the display panel 110.

A buffer layer BUF may be disposed on the substrate SUB.

A light blocking layer LS may be disposed on a portion of the buffer layer BUF. The light blocking layer LS may block external light and may prevent the characteristics of components disposed inside the display panel 110 from changing due to external light. Additionally, the light blocking layer LS may include a metal material, and may transmit an electrical signal.

A first interlayer dielectric layer ILD1 may be disposed to cover the light blocking layer LS. A contact hole may be formed in a portion of the first interlayer dielectric layer ILD1.

An active layer ACT may be disposed on the first interlayer dielectric layer ILD1.

A second interlayer dielectric layer ILD2 may be disposed to cover the active layer ACT and the first interlayer dielectric layer ILD1.

Electrodes SDE and GE for a driving transistor may be disposed on the second interlayer dielectric layer ILD2. To this end, a contact hole may be formed in a portion of the second interlayer dielectric layer ILD2. The electrodes SDE and GE for the driving transistor may include a gate electrode GAT and two source-drain electrodes SDE. One source-drain electrode SDE may be electrically connected to the light blocking layer LS.

A capacitor electrode pattern CP may be disposed on the first interlayer dielectric layer ILD1.

A passivation layer PAS may be disposed to cover the electrodes SDE and GE for the driving transistor and the second interlayer dielectric layer ILD2.

A color filter CF may be disposed on the passivation layer PAS.

An overcoating layer OC may be disposed to cover the color filter CF and the passivation layer PAS.

A pixel electrode PXL may be disposed on the overcoating layer OC. The pixel electrode PXL may be electrically connected to the source-drain electrode SDE through a contact hole formed in the overcoating layer OC.

A bank layer BNK may be disposed on the pixel electrode PXL and the overcoating layer OC.

An emission layer EL may be disposed on the bank layer BNK. The emission layer EL may be electrically connected to the pixel electrode PXL through a contact hole formed in the bank layer BNK.

Referring to FIG. 8, a first capping layer CPL1 may be disposed on a first cathode layer CAT1.

Referring to FIG. 8, a second cathode layer CAT2 may be disposed on the first capping layer CPL1. The second cathode layer CAT2 may be disposed to be spaced apart from the first cathode layer CAT1 in the display area DA.

Referring to FIG. 8, a second capping layer CPL2 may be disposed on the second cathode layer CAT2.

Referring to FIG. 8, an encapsulation layer EPAS may be disposed on the second capping layer CPL2.

Referring to FIG. 9, a first insulating layer IN1 may be disposed on the first cathode layer CAT1.

Referring to FIG. 9, a capping layer CPL may be disposed on the first insulating layer IN1.

Referring to FIG. 9, a second insulating layer IN2 may be disposed on the capping layer CPL.

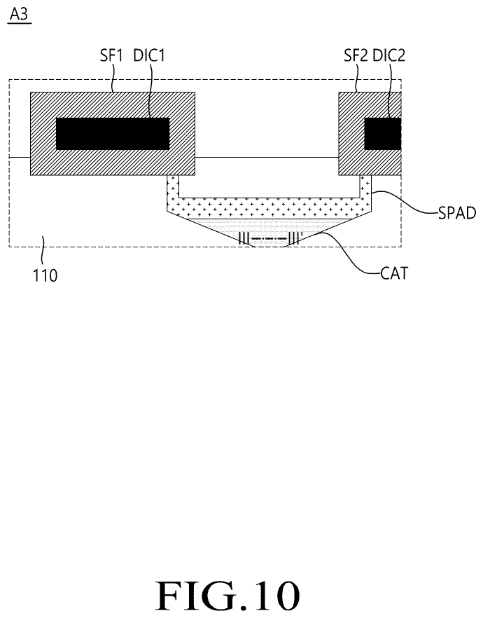

FIG. 10 illustrates a base voltage pad SPAD disposed on a display panel 110 according to embodiments of the present disclosure.

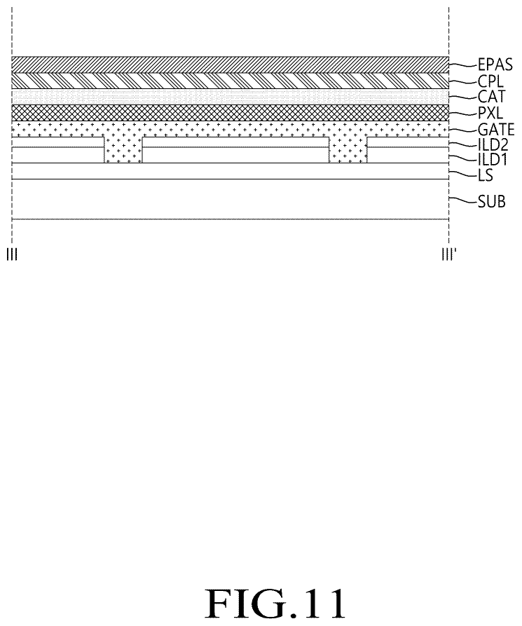

FIG. 11 is a cross-sectional view of a base voltage pad SPAD according to embodiments of the present disclosure.

Referring to FIG. 10, there is illustrated a third area A3 shown in FIG. 3.

Referring to FIG. 10, the display panel 110 may be electrically connected to a first source film SF1 and a second source film SF2.

Referring to FIG. 10, the first source film SF1 and the second source film SF2 may be connected to a base voltage pad SPAD.

Referring to FIG. 10, the base voltage pad SPAD may be electrically connected to a cathode layer CAT. The base voltage pad SPAD may be in physical contact with the cathode layer CAT.

Referring to FIG. 10, for convenience of explanation, the cathode layer CAT is shown in the area where the base voltage pad SPAD is disposed. Referring to FIG. 11, the cross-sectional structures of the cathode layer CAT and base voltage pad SPAD will be described in detail.

Referring to FIG. 11, there is illustrated a partial cross-sectional area of the base voltage pad SPAD. Referring to FIG. 11, the cathode layer CAT may be disposed in contact with a pixel electrode PXL. The base voltage pad SPAD shown in FIG. 10 may include a pixel electrode PXL, a gate electrode GATE, and a light blocking layer LS.

Referring to FIG. 11, a substrate SUB may be disposed at the bottom of the display panel 110.

The light blocking layer LS may be disposed on the substrate SUB.

A first interlayer dielectric layer ILD1 may be disposed on the light blocking layer LS.

A second interlayer dielectric layer ILD2 may be disposed on the first interlayer dielectric layer ILD1.

A gate electrode layer GAT may be disposed on the second interlayer dielectric layer ILD2. The gate electrode layer GAT may be electrically connected to the light blocking layer LS through a contact hole formed in the first interlayer dielectric layer ILD1 and the second interlayer dielectric layer ILD2.

The pixel electrode PXL may be disposed on the gate electrode layer GAT.

A cathode layer CAT may be disposed on the pixel electrode PXL.

A capping layer CPL may be disposed on the cathode layer CAT.

An encapsulation layer EPAS may be disposed on the capping layer CPL.

Since the display panel 110 shown in FIG. 11 is the same as the display panel 110 shown in FIGS. 4 and 5, there may be prevented the external substances from penetrating into the emission layer EL.

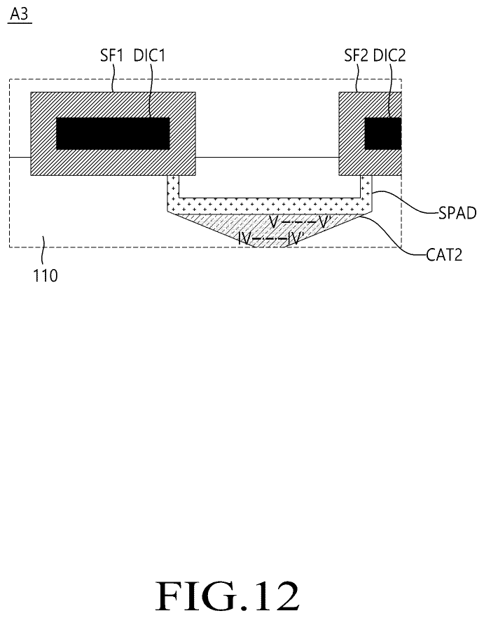

FIG. 12 illustrates a base voltage pad SPAD disposed on a display panel 110 according to embodiments of the present disclosure.

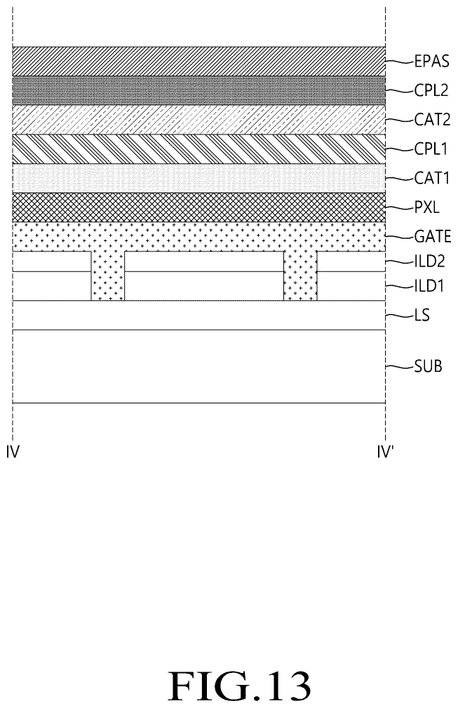

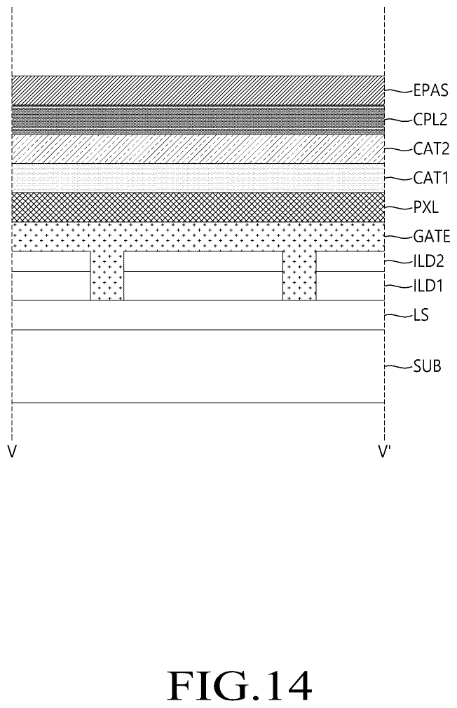

FIGS. 13 and 14 are cross-sectional views of base voltage pads SPAD according to embodiments of the present disclosure.

Referring to FIG. 12, for convenience of explanation, there is illustrated that the second cathode layer CAT2 is disposed in the area where the base voltage pad SPAD is disposed. The cross-sectional structures of the second cathode layer CAT2 and the base voltage pad SPAD are shown in FIGS. 13 and 14.

Referring to FIG. 12, the base voltage pad SPAD may be electrically connected to the first cathode layer CAT1. A portion of the first cathode layer CAT1 may be disposed to overlap a portion of an upper surface of the base voltage pad SPAD. At a position where the first cathode layer CAT1 and the base voltage pad SPAD overlap, the base voltage pad SPAD may be physically contacted with the first cathode layer CAT1.

The second cathode layer CAT2 may be disposed on the first cathode layer CAT1. Since the second cathode layer CAT2 is disposed to cover the first cathode layer CAT1, the upper end of the second cathode layer CAT2 may be disposed higher than the upper end of the first cathode layer CAT1. Referring to FIG. 12, there is illustrated the second cathode layer CAT2 and the base voltage pad SPAD, and a portion of the second cathode layer CAT2 may be disposed to overlap the base voltage pad SPAD. At a position where the second cathode layer CAT2 and the base voltage pad SPAD overlap, the base voltage pad SPAD may be physically contacted with the second cathode layer CAT2.

Referring to FIG. 12, there are illustrated a first cross-sectional area IV-IV′ and a second cross-sectional area V-V′ shown in the second cathode layer CAT2.

FIG. 13 illustrates a cross-sectional view of the first cross-sectional area IV-IV′, and FIG. 14 illustrates a cross-sectional view of the second cross-sectional area V-V′.

In the area IV-IV′ shown in FIG. 12, a first capping layer CPL1 may be disposed between a second cathode layer CAT2 and a first cathode layer CAT1. The area V-V′ shown in FIG. 12 may be an area where the first capping layer CPL1 is not disposed.

Referring to FIGS. 13 and 14, the first cathode layer CAT1 may be disposed in contact with the pixel electrode PXL. The base voltage pad SPAD shown in FIG. 12 may include a pixel electrode PXL, a gate electrode GATE, and a light blocking layer LS. That is, the base voltage pad SPAD may include a plurality of electrodes.

Referring to FIG. 13, the first cathode layer CAT1 may be disposed on the pixel electrode PXL. The first capping layer CPL1 may be disposed on the first cathode layer CAT1. The second cathode layer CAT2 may be disposed on the first capping layer CPL1. The encapsulation layer EPAS may be disposed on the second cathode layer CAT2. That is, the first capping layer CPL1 may be disposed in the area IV-IV′ shown in FIG. 12, and the second cathode layer CAT2 may be disposed to be spaced apart from the first cathode layer CAT1.

Referring to FIG. 14, the first cathode layer CAT1 may be disposed on the pixel electrode PXL. The second cathode layer CAT2 may be disposed on the first cathode layer CAT1. The encapsulation layer EPAS may be disposed on the second cathode layer CAT2. That is, the first capping layer CPL1 may be not disposed in the area V-V′ shown in FIG. 12, and the second cathode layer CAT2 may be disposed in contact with the first cathode layer CAT1. The first cathode layer CAT1 may be supplied with a base voltage. The base voltage supplied to the first cathode layer CAT1 may also be supplied to the second cathode layer CAT2. Accordingly, there may be alleviated the phenomenon of current being concentrated on the base voltage pad SPAD.

Referring to FIGS. 13 and 14, the first capping layer CPL1 may be disposed between the first cathode layer CAT1 and the second cathode layer CAT2 in the first cross-sectional area IV-IV′, however, may not be disposed between the first cathode layer CAT1 and the second cathode layer CAT2 in the second cross-sectional area V-V′. That is, in order for the first cathode layer CAT1 and the second cathode layer CAT2 to be disposed in contact with each other in the second cross-sectional area V-V′, the first capping layer CPL1 may be disposed only between the second cross-sectional area V-V′ and the first cross-sectional area IV-IV′.

Referring to FIG. 12, based on the first cross-sectional area IV-IV′, the relationship between lengths of the first cathode layer CAT1, the first capping layer CPL1, and the second cathode layer CAT2 may be as follow. The second cathode layer CAT2 may be disposed longest upward with respect to the first cross-sectional area IV-IV′, and the first capping layer CPL1 may be disposed shortest upward with respect to the first cross-sectional area IV-IV′. Therefore, the first capping layer CPL1 is shown in FIG. 13 but not in FIG. 14.

However, unlike the above description, the first capping layer CPL1 may be disposed shorter, and in this case, the first capping layer CPL1 may not be disposed in the first cross-sectional area IV-IV′. The first cathode layer CAT1 and the second cathode layer CAT2 may be disposed in contact with each other in the first cross-sectional area IV-IV′.

Embodiments of the present disclosure described above are briefly described as follows.

A display device according to embodiments of the present disclosure may include a substrate including a display area and a non-display area, an undercut protrusion disposed on the substrate and disposed in the non-display area, an emission layer including an undercut emission layer separated on the undercut protrusion, a first cathode layer disposed on the emission layer and including an undercut cathode layer separated on the undercut protrusion, and a first insulating layer disposed to cover the first cathode layer.

The display device according to embodiments of the present disclosure may further include a second cathode layer disposed on a first capping layer which is the first insulating layer, a second capping layer disposed on the second cathode layer, and an encapsulation layer disposed on the second capping layer.

The second cathode layer may be disposed in contact with the first cathode layer in the non-display area.

The second cathode layer may be disposed to be spaced apart from the first cathode layer in the display area.

The substrate may further include a base voltage pad to which a base voltage is supplied. The base voltage pad may include a first area in which the second cathode layer is disposed to be spaced apart from the first cathode layer, and a second area in which the second cathode layer is disposed in contact with the first cathode layer.

The first area may be an area where the first capping layer is disposed between the second cathode layer and the first cathode layer, and the second area may be an area where the first capping layer is not disposed.

The base voltage supplied to the first cathode layer may be also supplied to the second cathode layer.

The display device according to embodiments of the present disclosure may further include a capping layer disposed on the first insulating layer, and a second insulating layer disposed on the capping layer.

The first insulating layer and the second insulating layer may be inorganic layers.

The undercut protrusion may include an electrode disposed on the substrate, and a passivation layer disposed on the electrode.

The first insulating layer may be disposed between the passivation layer and the emission layer.

The first insulating layer may be disposed outside the emission layer corresponding to the display area.

The substrate may include a first area in which the passivation layer overlaps the electrode, and a second area in which the passivation layer does not overlap the electrode.

The first insulating layer may be disposed to surround the second area.

The display device according to embodiments of the present disclosure may further include a passivation layer disposed on the substrate in the display area, an overcoating layer disposed on the passivation layer, a bank layer disposed on the overcoating layer, a display area emission layer disposed on the bank layer and in the display area, and a display area cathode layer disposed between the first insulating film and the display area emission layer.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area and a non-display area;
an undercut protrusion on the substrate and disposed in the non-display area;
an emission layer including an undercut emission layer separated on the undercut protrusion;
a first cathode layer on the emission layer, the first cathode layer including an undercut cathode layer separated on the undercut protrusion; and
a first insulating layer disposed to cover the first cathode layer.

2. The display device of claim 1, further comprising:
a second cathode layer on a first capping layer which is the first insulating layer;
a second capping layer on the second cathode layer; and
an encapsulation layer on the second capping layer.

3. The display device of claim 2, wherein the second cathode layer is in contact with the first cathode layer in the non-display area.

4. The display device of claim 2, wherein the second cathode layer is spaced apart from the first cathode layer in the display area.

5. The display device of claim 4, wherein the second cathode layer is disposed to be spaced apart from the first cathode layer through the first capping layer in the display area.

6. The display device of claim 2, wherein the substrate further includes a base voltage pad to which a base voltage is supplied,
wherein the base voltage pad includes a first area in which the second cathode layer is spaced apart from the first cathode layer, and a second area in which the second cathode layer is in contact with the first cathode layer.

7. The display device of claim 6, wherein a portion of the first cathode layer is disposed to overlap with a portion of an upper surface of the base voltage pad.

8. The display device of claim 7, wherein the base voltage pad is in contact with the first cathode layer at a position where the first cathode layer and the base voltage pad overlap.

9. The display device of claim 6, wherein a portion of the second cathode layer is disposed to overlap with the base voltage pad.

10. The display device of claim 9, wherein the base voltage pad is in contact with the second cathode layer at a position where the second cathode layer and the base voltage pad overlap.

11. The display device of claim 6, wherein the second cathode layer is disposed to cover the first cathode layer and includes a portion not overlapping with the first cathode layer.

12. The display device of claim 6, wherein the first area is an area where the first capping layer is disposed between the second cathode layer and the first cathode layer, and the second area is an area where the first capping layer is not disposed.

13. The display device of claim 6, wherein the base voltage supplied to the first cathode layer is also supplied to the second cathode layer.

14. The display device of claim 1, further comprising:
a capping layer on the first insulating layer; and
a second insulating layer on the capping layer.

15. The display device of claim 1, wherein the undercut protrusion includes an electrode on the substrate, and a passivation layer on the electrode.

16. The display device of claim 15, wherein the first insulating layer is disposed between the passivation layer and the emission layer.

17. The display device of claim 1, wherein the first insulating layer is disposed outside the emission layer corresponding to the display area.

18. The display device of claim 15, wherein the substrate includes:
a first area in which the passivation layer overlaps the electrode; and
a second area in which the passivation layer does not overlap the electrode.

19. The display device of claim 18, wherein the first insulating layer is disposed to surround the second area.

20. The display device of claim 1, further comprising:
a passivation layer on the substrate in the display area;
an overcoating layer on the passivation layer;
a bank layer on the overcoating layer;
a display area emission layer on the bank layer and in the display area; and
a display area cathode layer between the first insulating film and the display area emission layer.
